(19) United States
(12) Patent Application Publication
(10) Pub. No.: US 2012/0103665 A1
(43) Pub. Date: May 3, 2012

(54) METHOD OF PROTECTING A PRINTED CIRCUIT BOARD AND RELATED APPARATUS

(76) Inventors: Kum Cheong Adam CHAN, Singapore (SG); Chee Yung Tan, Singapre (SG); Chen Chin Jimmy Wong, Singapore (SG)

(21) Appl. No.: 12/915,128

(22) Filed: Oct. 29, 2010

(51) Int. Cl. H05K 1/09; B23K 20/24; B23K 1/20

(52) U.S. Cl. 174/257; 228/175; 228/180.22

(57) ABSTRACT

According to one example there is a printed circuit board having a first surface and a solder mask over said first surface. There is a layer of sealing material having a shape and location covering a zone of the solder mask which is vulnerable to degradation.

### BACKGROUND OF THE INVENTION

It is conventionally recommended that power lines in a printed circuit board have at least a specified separation in order to maintain sufficient electrical isolation.

### BRIEF DESCRIPTION OF THE DRAWINGS

Examples of the invention will now be described, by way of non-limiting example only, with reference to the accompanying drawings, in which:

FIG. 1 (a) shows an example of a printed circuit board with a solder mask layer;

FIG. 1 (b) shows the printed circuit board of FIG. 1 (a) after a portion of the solder mask has been degraded by the solder reflow process;

FIG. 1 (c) shows the printed circuit board of FIG. 1 (a) with a layer of sealing material over the solder mask;

FIG. 2 shows an example of a printed circuit board with a plurality of patches of sealing material over selected zones of the solder mask;

FIG. 3 shows the printed circuit board of FIG. 2 as seen from above;

FIG. 4 shows an example of a printed circuit board having a component mounted thereon; and

FIG. 5 is a flow chart for a method of manufacturing a printed circuit board in one example.

### DETAILED DESCRIPTION

Circuitry in printed circuit boards (PCBs) is being packed into ever smaller areas and at higher densities. In some printed circuit boards a plurality of conducting lines may be in close proximity to each other. It is necessary, however, to ensure sufficient electrical isolation between the conducting lines of a printed circuit board so that no voltage breakdown occurs in the gap between them. This is even more important where the conducting lines are power lines. This problem arises in many types of apparatus; some examples are switches, routers, communication devices and communication devices which have both a communications function and a power supply function.

Electrical isolation of conducting lines at an outermost layer (a top or bottom layer) of a printed circuit board is typically provided by a layer of solder mask over a surface of the printed circuit board. Either or both of the top and bottom surfaces of a printed circuit board may have this layer of solder mask. In addition a minimum isolation distance is maintained between the conducting lines in order to provide sufficient electrical isolation. Due to space constraints power lines are often placed on an outermost layer (a top or bottom layer) of the PCB. With power lines the electrical isolation is clearly very important.

According to one conventional standard, the minimum electrical isolation of power lines in a printed circuit board should be 2 kV over one minute. To ensure this electrical isolation the standard requires an air gap of at least 120 mils between the power lines (approximately 3.048 mm; 1 mils is equal to 1/1000 of an inch).

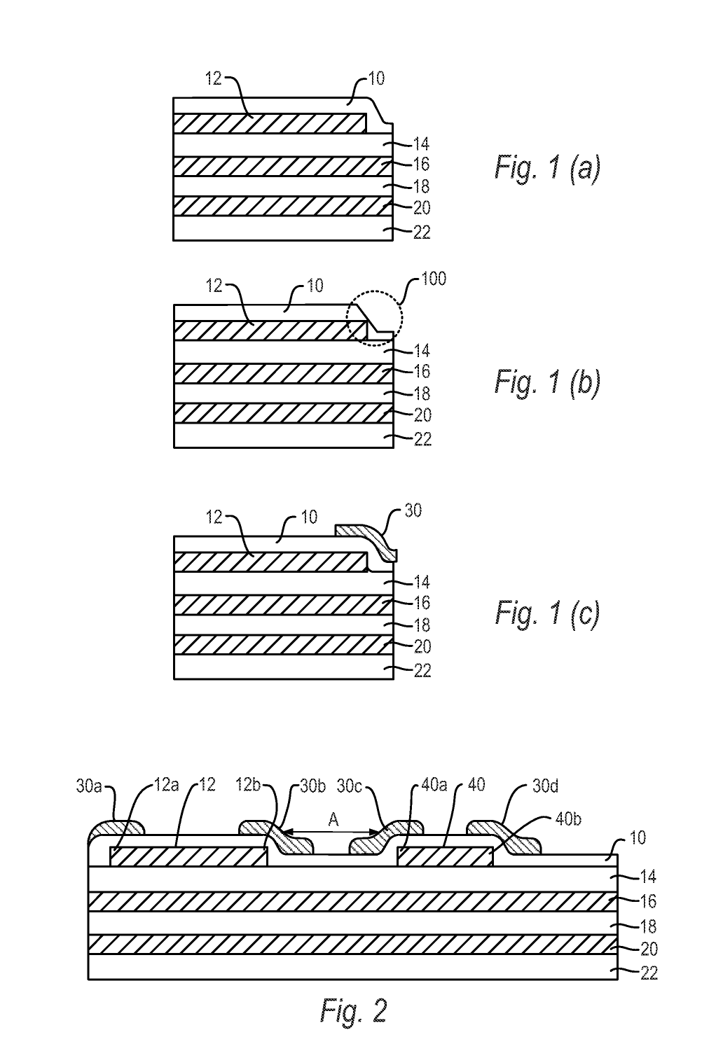

FIG. 1 (a) shows an example of a printed board. The printed circuit board comprises alternating layers of conducting material 12, 16, 20 and insulating material 14, 18, 22. The conducting layers comprise one or more conducting lines. The term ‘conducting line’ includes conducting lines, power lines and power panes. In one example conducting layer 12 is a power line. The term ‘power line’ includes both power lines and power panes.

A layer of solder mask 10 is provided over a first surface of the printed circuit board. The solder mask extends over the conducting line 12. The same reference numerals are used for like parts in FIGS. 1 (b), 1 (c) and 2.

During manufacture solder is passed over a surface of the printed circuit board and one or more components are mounted to bond pads of the printed circuit board and held in place by the solder. In one example, solder paste is applied to specific locations on the surface of the PCB (e.g. to the bond pads). One or more components are positioned at these locations and held in place by the solder paste. A solder reflow process is carried out during which the solder paste is heated to melt the solder. The melted solder forms a connection with the printed circuit board and the components and the components are thus fixed in place at the desired locations (e.g. on the bond pads).

The solder reflow process may degrade the solder mask. In particular, portions of the solder mask may be thinned or swept away by the solder reflow process. FIG. 1 (b) shows a printed circuit board in which a portion 100 of the solder mask 10 has been degraded. It can be seen that the solder mask in this region is thinner and thus provides less insulation and is vulnerable to voltage breakdown. Voltage breakdown means that the insulating property of the material is broken down, so that electrical current may pass through it; this may cause a short circuit between conducting lines or other electrical components on the PCB.

The portions of the solder mask which overlie a conducting line are vulnerable to being thinned during solder reflow. This is particularly the case for the portions near an edge of a conducting line as can be seen in FIG. 1 (b) which shows a conducting line 12. The portions near the edge of a conducting line are vulnerable to voltage breakdown. This is especially the case if the conducting line is a power line. If the power line is a high voltage line (e.g. 50 Volts or more) then the solder mask will be even more vulnerable to voltage breakdown.

FIG. 1 (c) shows an example of a printed circuit board having a layer of sealing material 30 over a selected portion or zone of the solder mask. The selected zone of the solder mask is selected for covering with sealing material 30 because it is vulnerable to degradation. The layer of sealing material has a shape and location which covers this selected zone. For example the selected zone may be vulnerable to thinning during the solder reflow process and/or vulnerable to voltage breakdown. In one example the selected zone is a portion of the solder mask which overlies an edge of a conducting line which is embedded in the PCB. The sealing material acts to seal the solder mask and helps to prevent it from being thinned or damaged, e.g. during solder reflow.

In one example the sealing material is a silk screen material. Silk screen material is convenient because it is cheap and can easily be applied to the surface of the PCB. It is easy to integrate application of a layer of silk screen material to a selected zone of the PCB as a step in the manufacturing process.

The sealing material may be an electrically insulating material. The insulating property of the material helps to prevent voltage breakdown and enhances the electrical isolation of the conducting line.

FIG. 2 shows an example of a PCB having a first surface and a layer of solder mask 10 over the first surface. In this example, four zones of the solder mask are selected for covering with sealing material. Each selected zone of the solder mask is a zone which overlies an edge of a conducting line embedded in the PCB. A patch of sealing material 30a is provided over a zone of the solder mask which covers an edge 12a of conducting line 12. The patch of sealing material 30a thus overlies the edge 12a of the conducting line 12. A patch of sealing material 30b overlies another edge 12b of the conducting line 12. In another example a patch of sealing material could overlie other parts or the whole of the conducting line 12 as well as the edge regions. A patch of conducting material 30c overlies an edge 40a of a second conducting line 40. A patch of conducting material 30d overlies another edge 40b of the conducting line 40. In one example, one or both of conducting lines 12 and 40 is a power line. In one example, one or both of the conducting lines 12 and 40 is a high voltage line.

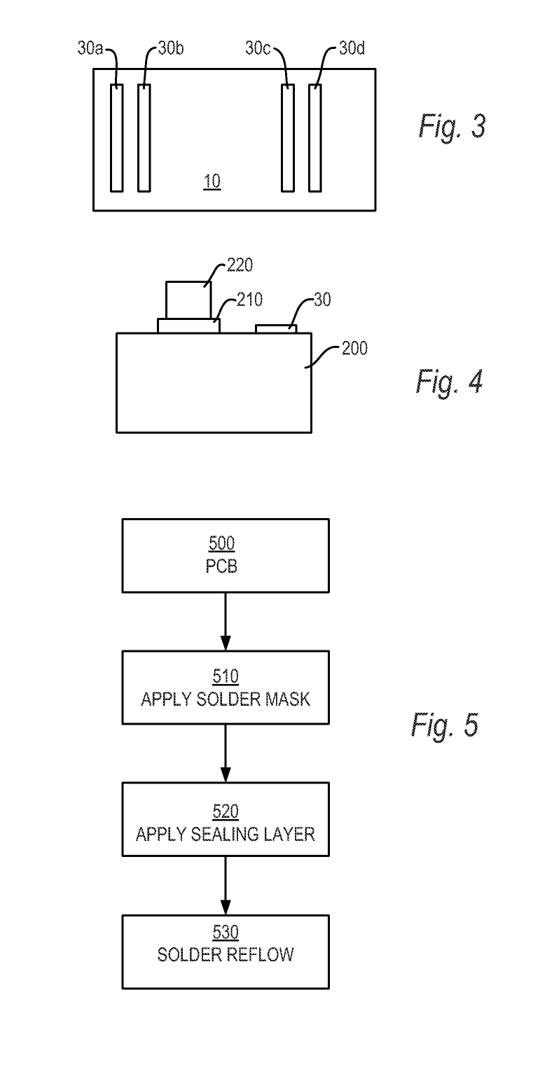

FIG. 3 is a view of the PCB of FIG. 2 from above. It shows four patches of sealing material 30a, 30b, 30c and 30d which are applied to selected zones of the solder mask 10 of the PCB. The shapes and locations of the patches of sealing material are such that they cover the selected zones of the solder mask. The patches of sealing material are solid blocks of sealing material, rather than writing or numbers. Their purpose is to protect the solder mask below, rather than to provide information about the contents of the PCB. The sealing material may be an insulating material. In one example the sealing material is a silk screen material.

FIG. 4 is a schematic diagram showing an example of a PCB 200 and a component 220 mounted on the PCB. The component 220 is mounted on a bond pad 210 on a first surface of the PCB. A layer of silk screen 30 is provided over another portion of the first surface of the PCB, which portion does not have a bond pad. That is, in this example, the silk screen layer does not extend over the bond pad. The component is not mounted by a ball grid array arrangement as ball grid array is not suitable for PCBs containing high voltage lines. Instead another mounting arrangement is used.

The example shown in FIG. 2 has two conducting lines 12 and 40. As selected zones of the solder mask are protected by patches of sealing material, the air gap between the conducting lines can be made smaller than would otherwise be the case, while still maintaining a sufficient degree of electrical isolation. In one example the separation distance A between the conducting lines 12 and 40 is less than 110 mils; in another example it is less than 100 mils; in another example it is less than 90 mils; in another example it is 80 mils or less. In one example, the electrical conducting lines 12 and 40 are high voltage lines and the electrical isolation of the conducting lines 12 and 40 from each other is at least 2 kV over a period of one minute.

The PCBs in this specification may be used in any apparatus which comprises a printed circuit board. By way of example only, the PCB may be used in a power supply related apparatus or a communications apparatus, but is not limited to these applications. A “power supply related apparatus” is an apparatus which provides a power supply like function. By way of example only, the following are all ‘power supply related apparatus’: a power supply, a communications device which has a communications feature and which also supplies power, a telephone, a switch with a routing feature which also supplies power, a PoE device (Power over Ethernet) etc.

FIG. 5 is a flow diagram showing steps in a method of manufacturing a PCB. In step 500 a PCB comprising insulating and conducting layers is provided. In step 510 a solder mask is applied over a first surface of the PCB. In step 520 a sealing layer is applied over selected zones of the solder mask in order to protect those selected zones from damage. In one example the sealing layer is a silk screen material. In step 530 a solder reflow is process is carried out in order to attach components to desired parts of the PCB (e.g. the bonding pads). The sealing layer protects vulnerable portions of the solder mask during the solder reflow process and helps to prevent undue thinning of the solder mask in those regions. This improves the electrical isolation of the PCB and helps to prevent voltage breakdown.

In some examples the layer of material covering selected zones of the solder mask may have an electrically insulating property. This electrical insulation may further help to enhance the electrical isolation of the PCB.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A printed circuit board having a first surface, a solder mask over said first surface and a layer of sealing material having a shape and location which covers a selected zone of the solder mask; said selected zone of the solder mask being a zone which is vulnerable to degradation.

2. The printed circuit board of claim 1 wherein said selected zone extends over an edge of a conducting line embedded in the printed circuit board.

3. The printed circuit board of claim 2 wherein the conducting line is a power line.

4. The printed circuit board of claim 1 wherein the sealing material is a silk screen material.

5. The printed circuit board of claim 1 wherein said printed circuit board comprises a high voltage line having a length and said selected zone of the solder mask overlies at least part of the high voltage line.

6. The printed circuit board of claim 5 wherein said layer of sealing material comprises a solid block of sealing material having a shape and location such that it extends over a substantial part of the length of said high voltage line.

7. The printed circuit board of claim 1 wherein said layer of sealing material comprises a plurality of patches of sealing material over a plurality of selected zones of the solder mask; said plurality of selected zones of the solder mask being zones which are vulnerable to degradation.

8. The printed circuit board of claim 7 having first and second power lines and wherein said selected zones overlie a portion of said power lines and wherein said power lines are separated from each other by an air gap of less than 100 mils.

9. The printed circuit board of claim 8 wherein the first and second power lines have an electrical isolation from each other of at least 2 kV.

10. A power supply related apparatus having a printed circuit board according to claim 1.

11. An apparatus comprising the printed circuit board of claim 1 and a component mounted on said printed circuit board, wherein said component is not mounted by a ball grid array.

12. A method of protecting the solder mask of a printed circuit board, the method comprising providing a patch of sealing material over a portion of the solder mask, said patch of sealing material having a shape and location such that it overlies a portion of the solder mask that is vulnerable to thinning during solder reflow.

13. The method of claim 12 wherein said portion overlies an edge of a conducting line embedded in the printed circuit board.

14. The method of claim 12 wherein the sealing material is a silk screen material.

15. The method of claim 12 wherein the sealing material is applied to the solder mask prior to solder reflow.

16. A method of manufacturing a PCB assembly comprising the step of applying a solder mask over a first surface of a PCB and protecting the solder mask by using the method of claim 12.

17. A printed circuit board having a first surface, a solder mask over said first surface and a layer of insulating material having a shape and location which covers a selected zone of the solder mask; said selected zone of the solder mask being a zone which is vulnerable to voltage breakdown.

18. The printed circuit board of claim 17 wherein the insulating material is a silk screen material.
